(19) United States
(12) Patent Application Publication
(10) Pub. No.: US 2025/0204282 A1
(43) Pub. Date: Jun. 19, 2025

(54) NON-VOLATILE MEMORY STRUCTURE WITH STACK IN VIA LOCATION AND CONDUCTIVE LINE ON THIS VIA

(71) Applicant: COMMISSARIAT A L'ENERGIE ATOMIQUE ET AUX ENERGIES ALTERNATIVES, Paris (FR)

(72) Inventors: Julien BORREL, Grenoble Cedex 09 (FR); Laurent GRENOUILLET, Grenoble Cedex 09 (FR); Carine JAHAN, Grenoble Cedex 09 (FR); Sébastien RICAVY, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/977,475

(22) Filed: Dec. 11, 2024

(30) Foreign Application Priority Data
Dec. 12, 2023 (FR) 2314040

(51) Int. Cl. H10N 70/00; H10B 63/00

(52) U.S. Cl. CPC H10N 70/066; H10B 63/00; H10N 70/023; H10N 70/8265

(57) ABSTRACT

A non-volatile memory structure formed of a stack including a lower electrode and an upper electrode and at least one active material between the lower electrode and the upper electrode, the stack of the non-volatile memory structure lining the side walls as well as a bottom of a trench and of a hole located in an extension of the trench, the hole and the trench being arranged in the insulating thickness, the stack being disposed at the bottom of the hole on a first conductive line.

### TECHNICAL FIELD

The present invention relates to the field of non-volatile memories formed from a stack of layers and including at least one active material layer between two electrodes. It relates more particularly to that of FeRAM ferroelectric memories, OxRAM resistive memories and ferroelectric tunnel junction (FTJ) memories.

The present invention provides for a microelectronic device with a non-volatile memory structure, of which the improved arrangement, as well as an improved method for manufacturing such a device.

### PRIOR ART

Ferroelectric memories or FeRAM memories have the quality of being non-volatile, that is to say being able to retain stored information even when the power supply thereof is switched off, consuming little energy, having short write and read times, being able to be integrated massively on chips with low operating voltages and possessing a low accessibility latency and good immunity to radiation. Furthermore, this type of memory has a very high write endurance. These memories have an operation based on the ferroelectric properties of the active material thereof placed between two electrodes. By applying a difference in potentials between the two electrodes creating an electric field of a value greater than the positive coercive field, the ferroelectric memory is placed in a high remanent polarisation state and by applying a difference in potentials creating an electric field of a value less than the negative coercive field, the ferroelectric memory is placed in a low remanent polarisation state. The high remanent polarisation state then corresponds to a given first logical state, for example ‘0’ and the low remanent polarisation state to a complementary logical state, for example ‘1’, which makes it possible to store the information.

Another type of so-called resistive memory such as OxRAM memories which stands for “Oxide Resistive RAM” relies for its part on an active material between two electrodes having at least two resistive states, corresponding to a high resistance state (HRS) and a low resistance state (LRS), under the application of a voltage. OxRAM memories have the main qualities of being non-volatile, having short write and read times, being able to be integrated massively on chips, and possessing low accessibility latency and good immunity to radiation and temperature. OxRAM memories typically have an M-1-M (Metal-Insulator-Metal) structure comprising an active material of variable electrical resistance, generally a transition metal oxide, disposed between two metal electrodes. The transition from the “HRS” state to the “LRS” state is governed by the formation and breakage of at least one conductive filament between the two electrodes. This conductive filament is created thanks to the presence of oxygen gaps in the active layer of the memory. By changing the potentials applied to the electrodes, it is possible to change the distribution of the filament and thus change the electrical conduction between the two electrodes. In the active layer, the electrically conductive filament is either broken or, on the contrary, reformed to vary the resistance level of the memory cell, during cycles for writing then resetting this cell (operations of SET, when the filament is reformed leading to the LRS state, and of RESET leading to the HRS state, when the filament is broken again by respectively applying a voltage of SET, VSET or RESET, VRESET at the electrode terminals).

Ferroelectric tunnel junction (FTJ) memories are memories using the change in electrical resistance of an active material of the ferroelectric type arranged between two electrodes to store information, with a low volatility, a high information density.

The aforementioned memories have the common point of being formed from a stack of layers including at least one active material arranged between two electrodes.

Currently, this type of memory stack is mainly produced in an ultimate metal interconnection level.

An example of one embodiment in an ultimate metal interconnection level is given in the document entitled “16 kbit HfO₂:Si-based 1T-1C FeRAM Arrays Demonstrating High Performance Operation and Solder Reflow Compatibility”, François, 2021 IEDM. This document provides in particular for a “2D” (in other words planar) arrangement of such a stack.

In order to increase the developed surface of the stack and improve performance, so-called “3D” arrangements have emerged. The document: “Ferroelectric deep trench capacitors based on Al:HfO2 for 3D non-volatile memory Applications”, Polakowski, 2014 IEEE International Memory Workshop (IMW) presents for example such a type of arrangement, wherein the arrangement extends into a particular region wherein a plurality of adjacent trenches have been formed.

Producing such an arrangement may require dedicating a particular area of a microelectronic device to the memory structure and additional and specific photolithography steps. It also causes difficulties in establishing contact with the lower or upper electrode.

There is therefore a need to overcome one or more of the abovementioned drawbacks.

### DESCRIPTION OF THE INVENTION

According to one aspect, the present invention provides for a microelectronic device comprising:
a substrate including a plurality of superimposed metal interconnection levels,
a non-volatile memory structure arranged on a first conductive line of a first metal interconnection level, the non-volatile memory structure comprising a stack including a lower electrode and an upper electrode and at least one active material layer between the lower electrode and the upper electrode, the device further comprising:
the first conductive line of the first interconnection level, and a second conductive line of said first metal interconnection level, the second conductive line being distinct from the first conductive line, the first conductive line and the second conductive line being arranged in the same first plane parallel or substantially parallel to a main plane of the substrate,
a third conductive line belonging to a second upper metal interconnection level in relation to said first interconnection level, the third conductive line being arranged in a second plane parallel to the main plane of the substrate and above the first plane such that the first plane is arranged between the second plane and the main plane of the substrate, the third conductive line being connected to the second conductive line by means of a conductive via, the conductive via extending into an intermediate region between said first plane and said second plane, the lower electrode, the upper electrode and said at least one active material layer of said stack of the non-volatile memory structure extending into said upper metal interconnection level and into said intermediate region.

With such a configuration, it is possible to implement a memory stack with a large developed surface while limiting the size in the plane of the memory structure and moving away from a so-called “front-end” area corresponding to the level wherein components such as transistors are formed.

The non-volatile memory (NVM) structure may advantageously comprise a given cross-sectional upper part and a cross-sectional lower part different from the given cross section.

Advantageously, the third conductive line and the conductive via passing through an insulating thickness, the insulating thickness extending over the first conductive line and the second conductive line, said stack of the non-volatile memory structure lining the side walls as well as a bottom of a trench and of a hole located in the extension of this trench, the hole and the trench being arranged in said insulating thickness, the stack being disposed at the bottom of the hole on the first conductive line.

Advantageously, the hole is provided with a width W1 and the trench is provided with a width W2 such as W2>W1, such that the non-volatile memory structure includes a lower portion and an upper portion enlarged in relation to the lower portion. Such a configuration facilitates the contact on the upper part of the memory structure.

According to a possible implementation, the cumulative height H of the hole and of the trench is substantially equal to the cumulative height hc of the conductive via and of the third conductive line.

Such a configuration contributes to the implementation of a memory structure integrated into the standard/conventional interconnection levels and having a large developed surface but without having to provide for specific design rules to design it.

According to a possible implementation the method further comprises:
a first upper conductive via having a lower end disposed on and in contact with the non-volatile memory (NVM) structure and extending, in an insulating thickness, between this lower end and an upper end,
a second upper conductive via having a lower end disposed on and in contact with the third conductive line, and extending in said insulating thickness between the lower end thereof and an upper end,

the first upper conductive via and the second upper conductive via having respectively equal heights measured between the lower end thereof on the one hand and the upper end thereof on the other hand.

Advantageously, said conductive via has a lower end in contact with the second conductive line and an upper end in contact with the third conductive line, said conductive via and the third conductive line being arranged in at least one insulating layer, a lower face of the insulating layer being disposed on and in contact with the first conductive line and with the second conductive line,

the non-volatile memory structure extending entirely in said insulating layer, between the lower face of the insulating layer and a plane passing both through an upper face of the insulating layer opposite the lower face, the lower end of the first upper conductive via and through the lower end of the second upper conductive via.

According to a possible implementation, the lower electrode, the upper electrode and the at least one active material layer of said stack of the non-volatile memory (NVM) structure extend in the form of a fourth conductive line, distinct from the third conductive line and belonging to the second metal interconnection level and in the form of at least one other conductive via in the extension of the fourth conductive line and to contact the first conductive line.

In this case, advantageously, the fourth conductive line and said other via, have a cross-sectional profile (or a cross section) substantially identical to that (resp. that) of the third conductive line and of said conductive via.

Advantageously, the device may also be provided with an additional conductive via arranged on and in contact with an upper portion of the memory structure.

Preferably, the upper electrode is provided with or coated with an area of conductive material for filling the hole and the trench, the additional conductive via being disposed on and in contact with the upper portion of the memory structure without being disposed in contact with the active material or the lower electrode.

Similarly, advantageously, another additional conductive via may be provided on the third conductive line.

Thus, according to a possible implementation, one or more additional conductive or metal interconnection levels may be provided on or above the non-volatile memory structure.

According to a first particular implementation, the non-volatile memory structure may be of the FeRAM type, the active material being then formed of a ferroelectric dielectric layer.

According to an alternative implementation, the non-volatile memory structure may be of the OXRAM type, the active material being formed of at least one dielectric oxide layer.

According to another alternative implementation, the non-volatile memory structure may be of the FTJ type, the active material being formed of at least one ferroelectric dielectric layer in contact with a layer of another dielectric material.

According to another alternative implementation, the non-volatile memory structure may be of the CBRAM type, the active material being formed of at least one electrolyte layer.

According to another aspect, the present invention provides for the implementation of a method for producing a microelectronic device as defined above.

According to another aspect, the present invention relates to a method for manufacturing a microelectronic device provided with a non-volatile memory (NVM) structure formed of a stack including at least one lower electrode and at least one upper electrode and at least one active material between the lower electrode and the upper electrode, the method comprising the following steps of:
providing a substrate coated with at least one insulating layer, a first conductive line and a second conductive line of a given interconnection level (Mx−1) extending in the insulating layer and in the same first plane parallel to a main plane of the substrate,
forming an insulating thickness on the first conductive line, the second conductive line and said insulating layer,
forming in said insulating thickness, a hole revealing the first conductive line and a trench in the extension of this hole,
depositing in the trench and in the hole a stack comprising at least one lower electrode layer, at least one active material layer and at least one upper electrode layer, said stack lining the side walls and a bottom of the hole and of the trench.

Such a method makes it possible to reconcile a large developed surface of the memory structure and the size of this structure.

Such a method also makes it possible to produce the memory structure without necessarily providing for specific design rules.

In addition to the aforementioned advantages, producing the stack at a distant level of the components formed in a semiconductor layer of the substrate makes it possible to preserve it from steps with a high thermal budget.

Advantageously, the deposition in the trench and in the hole of said stack is followed by filling the trench and the hole by depositing a metal material, so as to fill the hole and the trench.

The deposition of the stack is typically a compliant deposition and may advantageously be performed by ALD.

According to a possible implementation, the method may further comprise forming in the insulating thickness a conductive via in contact with the second conductive line and a third conductive line on the conductive via.

According to a first possible implementation of the method, producing the conductive via and the third conductive line may comprise steps of:
producing a first masking facing the first conductive line and including at least one opening facing the second conductive line,
etching through the opening of the first masking another trench and another hole in the extension of the other trench and having a bottom revealing the second conductive line,
filling the other trench and the other hole using at least one conductive material,

the method further comprising:
removing the first masking and forming a second masking including at least one opening facing the first conductive line, etching the insulating thickness through the opening of the second masking to form the trench and the hole.

According to a second possible implementation of the method, producing the conductive via and the third conductive line may comprise forming another trench and another hole in the extension of the other trench, the other hole having a bottom revealing the second conductive line, the hole revealing the first conductive line and the other hole revealing the second conductive line being formed concomitantly.

Advantageously, the trench, the other trench, the hole, and the other hole may be formed by etching the insulating thickness through one or more openings of a first masking. The method may then further comprise steps of:
filling the trench, the other trench, the hole and the other hole using at least one conductive material,
removing the first masking and forming a second masking facing the second conductive line and the third conductive line, the second masking including at least one opening facing the first conductive line,

the method further comprising steps of:
removing the conductive material from the trench and from the hole by etching through the opening of the second masking, so as to release the trench and the hole again,
forming the stack in the trench and the hole.

According to a possible implementation the active material layer(s) may be formed:
of a ferroelectric dielectric, in particular an oxide such as Si-doped HfO₂ or HfZrO₂, or
of a dielectric oxide such as HfO₂, or
of an electrolyte layer, in particular based on a metal oxide such as HfO2 or Al2O3 or Ta2O5 or based on a chalcogenide such as GeSe or GeTe or GeSbTe,
of a stack of a ferroelectric dielectric and of another dielectric.

Preferably, the other dielectric is selected so as to present a large gap (i.e. a significant difference between the valence band thereof and the conduction band thereof) in order to have a significant tunnel resistance at a low thickness.

According to one possible implementation, the lower electrode and the lower electrode may be formed:
of a layer made of a first material selected in particular from one or more of the following materials: Ti, TiN, W
of a layer made of a metal material selected in particular from one or more of the following materials: W, Cu, Al, AlCu, AlSi.

### BRIEF DESCRIPTION OF THE DRAWINGS

The present invention will be better understood upon reading the description of examples of embodiments given purely by way of illustrative and non-limiting examples, making reference to the appended drawings wherein:

FIGS. 1A and 1B illustrate a particular arrangement of a non-volatile memory structure formed of a stack and integrated at the same level as that respectively of a conductive via and of an interconnection conductive line.

FIGS. 2A, 2B and 2C illustrate various examples of stacks of which the non-volatile memory structure is likely to be formed.

FIG. 3 illustrates an example of a possible starting substrate for implementing a microelectronic device according to the invention.

FIGS. 4A to 4F illustrate a first example of method for manufacturing a non-volatile memory structure formed of a stack in an insulating thickness wherein one or more conductive vias and one or more conductive lines of a metal interconnection level are also formed.

FIGS. 5A to 5D illustrate a second example of a method for manufacturing a non-volatile memory structure for which the location of the stack in the form of a hole and of a trench in an insulating thickness is produced at that of a conductive via and a conductive line in this same thickness.

FIGS. 6A and 6B illustrate stack arrangements that are not part of the claimed invention.

FIG. 7 illustrates an example of embodiment wherein the non-volatile memory structure is formed of a stack of layers and is connected to a conductive via disposed on this stack.

FIG. 8 illustrates a particular arrangement of a non-volatile memory structure with an upper part that forms a conductive line.

Identical, similar or equivalent parts of the various figures bear the same reference numerals so as to make it easier to switch from one figure to another.

The various parts shown on the figures are not necessarily according to a uniform scale, in order to make the figures more legible.

### DETAILED DESCRIPTION OF PARTICULAR EMBODIMENTS

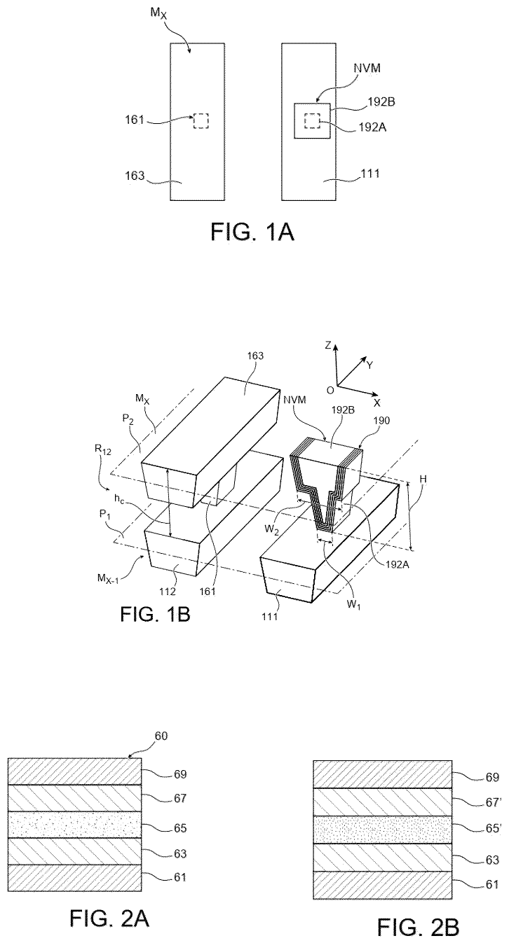

Firstly, reference is made to FIGS. 1A and 1B respectively giving, according to a top view and according to a perspective view, an example of a non-volatile memory NVM structure formed in an interconnection level Mx (with x greater than or equal to 1 and typically at least equal to 3) of a microelectronic device.

The non-volatile memory NVM structure is produced here in a level commonly called “back end” of the device, above an underlying “front-end” level and wherein the semiconductor components and in particular the transistors are provided.

The non-volatile memory NVM structure may for example be of the FeRAM, or OxRAM or FTJ or CBRAM type and is provided with a lower portion 192A disposed on and in contact with a first conductive line 111, here a metal line of a given interconnection level Mx−1 from a plurality of metal interconnection levels of the microelectronic device.

This lower portion 192A may be in the form of a conductive via and is located at the same level as another conductive via 161. “Conductive via” means a so-called “vertical” conductive element and extending between two conductive lines of different levels and located in distinct planes.

The conductive via 161 ensures here the connection between a second conductive line 112 of the same given level Mx−1 as the first line 111 and a third conductive line 163 of a level Mx higher than the given level. The first conductive line 111 and the second conductive line 112 are thus arranged in the same first plane P₁. The first conductive line 111 and the second conductive line 112 are distinct and preferably non-connected and/or non-secant.

The non-volatile memory NVM structure also includes an upper portion 192B disposed at the same level Mx as the third conductive line 163. The third conductive line 163 is arranged here in the same second plane P2, parallel to the first plane P1, as the upper portion 192B of the NVM structure.

Preferably, the level Mx does not correspond to the last “back-end” level of the device so that there are one or more metal levels higher than the level Mx. Thus, one or more additional levels (not shown) of conductive lines may be provided above the third conductive line 163. The non-volatile memory NVM structure is therefore advantageously provided here between the “front end” part of the device and the ultimate “back-end” level whereon contact pads or bosses are typically arranged.

The upper portion 192B of the memory NVM structure may be provided here with a width W2 or critical dimension greater than the width or critical dimension W₁ of the upper portion 192A (W₁ and W₂ being dimensions measured parallel to the axis x in FIG. 1B and that correspond to the smallest dimension of a pattern measured parallel to the plane [O;x;y]). The width W₂ may advantageously be provided in the order of that of a conductive line 163 located at the same level, for example between 20 nm and 60 nm.

The cumulative height H of the lower portion 192A and of the upper portion 192B may be provided in the order of that cumulative of the conductive via 161 and of the conductive line 163. Thus, the arrangement of the memory NVM structure here does not necessarily induce modification of design rules or loss of density.

The non-volatile memory NVM structure is formed of a stack 190 comprising at least one lower electrode and one upper electrode as well as at least one active material arranged between the lower electrode and the upper electrode. The lower electrode, the upper electrode and the active material of this memory stack extend here both into the upper metal interconnection level Mx and into an intermediate region R₁₂ located between the first plane P1 and the second plane P2.

Various stack compositions may be considered depending on the type of memory NVM structure implemented.

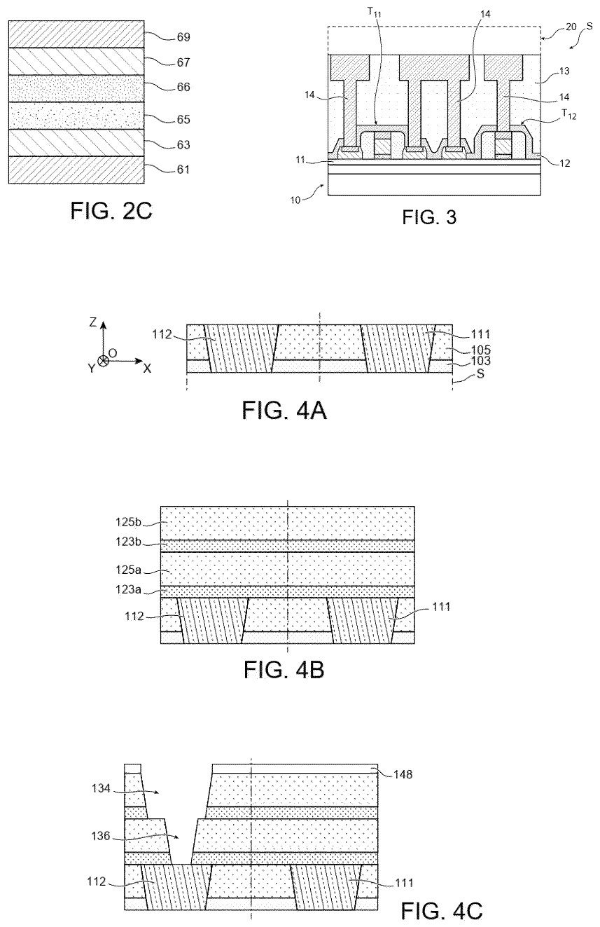

A particular example of stack 60 is given in FIG. 2A for a structure of the FeRAM type. It is provided with a lower electrode layer 63, coated with a ferroelectric dielectric layer 65, itself coated with an upper electrode layer 67. Advantageously, the lower electrode layer 63 may be disposed on and in contact with a metal layer 61. Similarly, a metal layer 69 may advantageously be disposed on and in contact with the upper electrode layer 67. The ferroelectric dielectric layer 65 may for example be based on HfO₂ doped in particular with Si or based on HfZrO₂, optionally doped, for example with lanthanum (La), or with aluminium (Al). The lower and upper electrode layers 63, 67 may be formed for example based on TiN or W or a stack of Ti and TiN for the lower electrode layer 63. 61. The metal layers 61, 69 for their part may for example be provided based on W, Cu, Al, AlCu, AlSi.

A particular example of stack for implementing a NVM structure of the OxRAM type is given in FIG. 2B. It differs particularly from the stack described above due to the composition of at least one of the electrodes thereof, here by the top electrode layer 67′, preferably containing an oxidisable conductive material such as for example Ta or Ti or Hf. The active layer disposed between the electrodes is a dielectric 65′ of the dielectric oxide type, in particular an oxide of one of the oxidisable conductive materials mentioned above, for example HfO₂.

Another example of stack is given in FIG. 2C in order to form this time a non-volatile memory structure of the FTJ type. The active layer located between the electrodes here has the specific feature of being formed of a stack of dielectric layers 65, 66 based on distinct dielectric materials. A first dielectric layer 65 corresponds in this particular example to a ferroelectric dielectric for example of Si-doped HfO₂ or HfZrO₂, this first dielectric layer is coated here with a second dielectric layer 66 for example based on Al2O₃.

For the sake of simplification, one or other of the stacks of the figures shown in FIGS. 2A, 2B, 2C are disposed in planar form. However, as can be seen in FIG. 1B, a particular stack arrangement distributed in 3D over several distinct and non-parallel planes is provided here so as to give the memory NVM structure a significant developed surface while limiting the size in the plane (in other words in a direction parallel to the plane [O;x;y] in FIG. 1B.

An improvement of the developed surface of the memory NVM structure makes it possible, in particular when it concerns a FeRAM, to increase the memory window thereof and to better separate the memory states thereof. Such an improvement makes it possible, particularly when it concerns an FTJ, to obtain a reduction in the total resistance of the structure and to be able, at a constant current density, to increase the injected current. When the NVM structure is of the OxRAM type, an increase in the developed surface makes it possible to reduce the so-called “forming” voltage necessary to modify the conductive state thereof by creating conductive filaments and therefore limit consumption.

As an alternative to the examples described above, it is possible to provide a NVM structure formed of a memory stack of the CBRAM type, including between a lower electrode and an upper electrode, at least one electrolyte layer.

One of the electrodes may for example be made of Cu or Ag, whereas the other electrode is provided made of Pt or TiN or TaN or W. The active material forming the electrolyte may for example be a chalcogenide for example GeSe, or GeTe, or GeSbTe or a metal oxide such as HfO₂, or Al₂O₃, or Ta₂O₅.

Reference is now made to FIG. 3, which illustrates an example of a possible structure S from which a device as described above may be formed.

This structure S comprises a substrate 10 whereon one or more electronic components, in particular transistors T₁₁, T₁₂ are arranged. The transistors T₁₁, T₁₂ have a channel region arranged in a superficial semiconductor layer 11 of the substrate 10. The substrate 10 may for example be a solid substrate or a substrate of the semiconductor-on-insulator type and in particular of the SOI (Silicon On Insulator) type.

The transistors T₁₁, T₁₂ are covered here with one or more insulating layers 12, 13 through which one or more conductive elements 14 passing through, connected to the transistor(s) are provided. Manufacturing steps of the type commonly referred to as “front-end-of-line” (FEOL) where components (transistors, capacitors, resistors) are formed from a semiconductor layer of the substrate have thus been carried out here to produce such a device.

The assembly may subsequently advantageously be covered with a part, schematically shown by a block 20 in a discontinuous line, formed of one or more insulating layers and of at least one metal interconnection level or level formed of vias and horizontal conductive lines in this or these insulating layers.

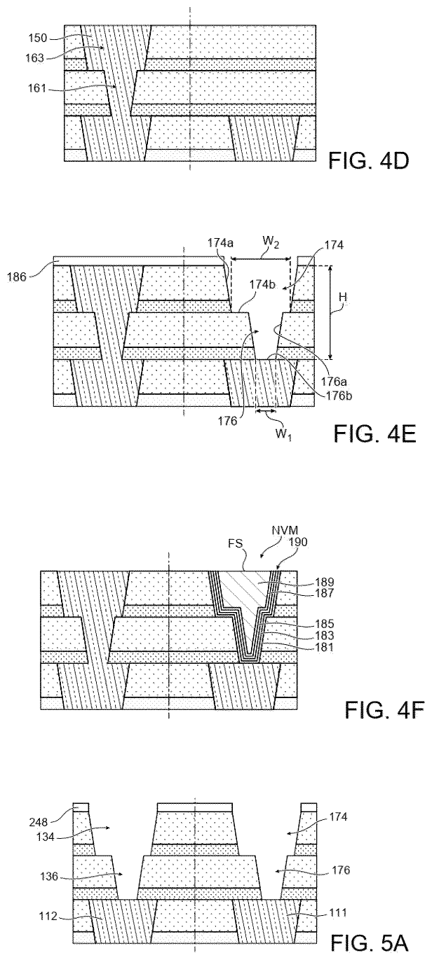

A first example of a method for producing a microelectronic device as described above will now be given in connection with FIGS. 4A-4F.

The structure S described above is used here in this example as a starting structure for the process.

Firstly, this structure S is coated with one or more insulating layers, here for example with a stack of an insulating layer 103 made of a first material such as for example silicon nitride and another insulating layer 105 made of a second material such as for example silicon oxide.

A first conductive line 111 of an x−1^{st} (with x greater than or equal to 2) interconnection level Mx−1 and a second conductive line 112 of the same metal interconnection level Mx−1 are subsequently formed. For this purpose, trenches are typically produced in the insulating layers 103, 105 that are subsequently filled with at least one conductive material, for example Cu.

The first conductive line 111 and the second conductive line 112 formed (FIG. 4A) are arranged in the same first plane parallel or substantially parallel to a main plane of the substrate (i.e. a plane passing through the substrate 10 in the structure S and that is parallel to the plane [O;x;y] of the reference [O;x;y;z] given in FIG. 4A).

One or more insulating layers are subsequently formed covering the first conductive line 111 and the second conductive line 112 and the insulating layer 105. In the example of embodiment illustrated in FIG. 4B, a stack formed of an alternation of layers 123a, 123b made of a first insulating material such as for example silicon nitride and of layers 125a, 125b made of a second insulating material such as silicon oxide is produced.

At least one trench 134 and at least one hole 136 located in the extension of this trench 134 are subsequently formed in the insulating thickness 123a-125b thus created. The trench 134 has here a critical dimension (smaller dimension measured parallel to the main plane of the substrate) greater than that of the hole 136. Typically, the trench 134 extends mainly in a horizontal direction, in other words parallel to the main plane of the substrate, whereas the hole 136 extends mainly in a direction producing a non-zero angle with that of the trench 134 and preferably vertical, in other words orthogonal to the main plane of the substrate.

To produce the trench 134 and the hole 136 in the extension thereof, it is possible to proceed in different ways.

A commonly-called “via-first” method consists in producing an opening through the entire insulating thickness 123a-125a to form the hole 136 then the trench 134 is formed in the insulating layers 123b-125b. Another commonly-called “line-first” method consists in producing an opening through the upper insulating layers 125b-123b to form the trench 134, then etching the bottom of the trench 134 in order to produce the hole 136 in the insulating layers 123a-125a and in the extension of this trench 134.

The etching(s) of the insulating thickness 123a-125a to form the hole 136 and the trench 134 are typically carried out through at least one opening of a masking 148 disposed facing the first conductive line 111. The masking 148 may be a resin mask, in particular of photosensitive resin or a hard mask, for example of amorphous carbon. For example, dry etching based on CF₄ may be implemented.

Subsequently, the trench 134 and the hole 136 are filled using at least one conductive material 150, which may be formed of a stack of a plurality of metal layers, for example a stack of TaN, of Ta, and of Cu. Such filling is typically performed as in FIG. 4D, after removing the first masking 148, by deposition then CMP (Chemical Mechanical Polishing) planarisation.

The trench 134 filled with conductive material 150 forms a third horizontal conductive line 163, whereas the hole 136 filled with conductive material 150 forms a conductive via 161 in other words a vertical conductive element. The third conductive line 163 produced thus belongs to an x^{th} level Mx of conductive or metal lines.

A hole 176 having a bottom revealing the first conductive line 111 is subsequently formed in the insulating layer(s) 123a-125a and a trench 174 is formed in the insulating layer(s) 123b-125b. Similarly, for this purpose, a sequence of steps of the “line first” or “via first” type may be performed. The trench 174 has here a critical dimension W2 (smaller dimension measured parallel to the main plane of the substrate) greater than that W1 of the hole 176 and typically extends mainly in a horizontal direction. The hole 176 extends in a typically vertical direction.

A memory stack 190 is subsequently formed comprising at least one lower electrode layer, at least one active material layer and at least one upper electrode layer, the active material layer being arranged between the lower electrode layer and the upper electrode layer. The stack is produced so as to line the side walls 174a and the bottom 174b of the trench 174 and to line the side walls 176a and the bottom 176b of the hole 176. In the case of a FeRAM stack, the lower electrode layer may for example be based on W, or TiN, or formed of a Ti/TiN stack. The upper electrode layer may for example be based on W, or TiN. The active material layer may be a ferroelectric dielectric layer such as for example silicon-doped HfO₂ or HfZrO₂.

According to a particular example of embodiment illustrated in FIG. 4F, to form the lower electrode, the hole 176 and the trench 174 are first lined with a stack of layers 181, 183 for example based on Ti and TiN and with a thickness of for example between 5 nm and 20 nm. A layer 185 of ferroelectric dielectric for example based on HfZrO₂ and with a thickness of for example between 5 nm and 15 nm is subsequently deposited. Then, a layer 187 for example based on TiN and with a thickness that may be for example between 5 nm and 20 nm is deposited. The layers 181, 183, 185, 187 may for example be formed by a method of the ALD (Atomic Layer Deposition) type in order to obtain a compliant distribution on the side walls of the trench 174 and of the hole 176 as well as at the bottom of the hole 176. It is subsequently possible to finish filling the trench 174 and the hole 176 by depositing a metal material 189, for example such as W. The trench 174 and the hole 176 are then preferably completely filled. The central region of the memory structure is thus mainly formed of this metal material 189.

In the example of embodiment just described, the conductive via 161 and the third conductive line 163 are formed before even producing the hole 176 and the trench 174 wherein the non-volatile memory NVM stack is provided.

An alternative embodiment provides for concomitantly forming the holes 136, 176 for receiving respectively the conductive via and the memory stack. Preferably, the production of the trenches 174, 184 for receiving respectively the third conductive line 163 and the memory stack is also carried out concomitantly.

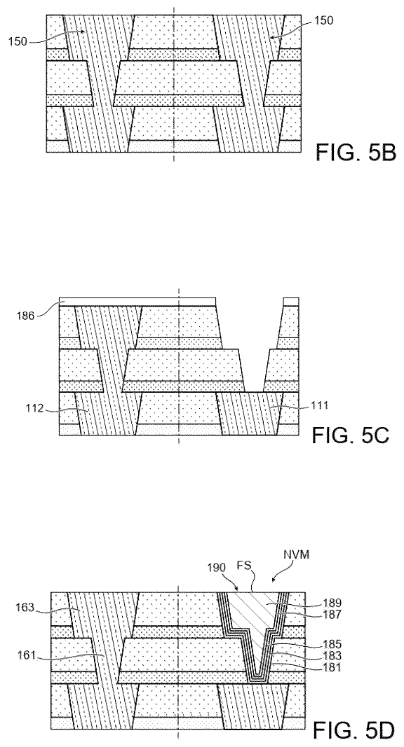

Thus, in the example of embodiment illustrated in FIG. 5A, after having formed the conductive lines 111, 112 then covered these lines with the thickness 123a-125b of insulating layers, the holes 176, 136 and the trenches 174, 134 are formed, by a “line first” or “via first” method, by carrying out one or more concomitant etches in the insulating thickness 123a-125b. Etching may be implemented through a masking 248.

Subsequently (FIG. 5B), filling of the holes 136, 176 and trenches 134, 174 is carried out by way of at least one conductive material 150, typically deposited concomitantly in the holes 176, 136 and in the trenches 174, 134 and for example formed of a stack of TaN, of Ta, and of copper.

Then, a masking 186 is formed facing the second conductive line 112 and the third conductive line 163. This masking 186, typically in the form of photosensitive resin or of a hard mask, does not extend facing the first conductive line 111 and thus includes an opening facing the first conductive line 111.

Removal of the conductive material 150 from the hole 176 and rom the trench 174 not protected by the masking 186 is subsequently carried out (FIG. 5C). Etching, for example using wet etching, typically using HNO₃ or NH₄OH may be implemented for this purpose.

Then, after removing the masking 186 for example using a plasma, the hole 176 and the trench 134 are subsequently filled again using this time a memory stack. A memory stack of layers 181, 183, 185, 187, 189 as described above may for example be used or a stack as described above in connection with one or the other of FIGS. 2A to 2C.

As an alternative embodiment to one or other of the examples of embodiments described above, it is possible to form the NVM structure from a structure different from that described in FIG. 3. For example, it is possible to start from a structure as illustrated in FIG. 4A and wherein the conductive lines 111, 112 have already been produced or from a structure as in FIG. 4B and wherein the conductive lines 111, 112 have already been produced and covered with an insulating thickness.

The memory NVM structure, the embodiment of which has just been described has, due to the configuration of the trench and of the hole wherein it is formed particularly as it has the specific feature of having at the upper face FS thereof an area occupied by the upper electrode and the metal material(s) in contact with this electrode much larger than that of the active material layer(s) and the lower electrode. This makes it possible to facilitate contact with the upper electrode and prevents short circuits.

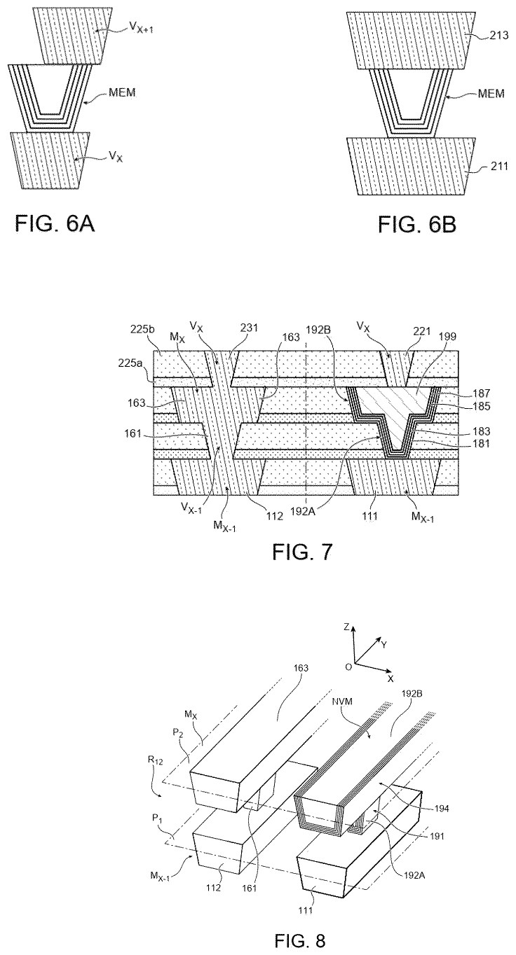

In an alternative embodiment illustrated in FIG. 6A, which is not part of the present invention and where a memory stack MEM is formed only in a hole portion between two portions of conductive vias Vx+1, Vx, there is a risk, unlike the proposed arrangement for the NVM structure, of producing a short circuit in the event of misalignment.

Similarly, in another alternative embodiment illustrated in FIG. 6B (which is not part of the present invention) where a memory stack MEM is formed only in a via hole between two conductive lines 211, 213 of distinct levels, a short circuit is created, unlike the proposed arrangement for the NVM structure.

Once the memory structure NVM has been formed, other additional metal interconnection levels may subsequently be produced on the level Mx wherein the third conductive line 163 and the upper part of the NVM structure are located.

Thus, it may be provided to form particularly a conductive element or a conductive via 221 on the NVM structure the embodiment of which has just been described. In the particular example of embodiment illustrated in FIG. 7, this conductive via 221 contacts the enlarged upper portion 192A of the stacked memory structure and in particular a layer or the filling metal material 199 forming the electrode or disposed on the upper electrode of the memory NVM structure. The shape of this upper portion and the configuration of the stack of layers 181, 183, 185, 187, 189 forming the NVM structure makes it possible here to prevent any risk of short circuit.

The conductive via 221 may be arranged at the same via level Vx as another conductive via 231 contacting it on the third conductive line 163 of level Mx of metal lines.

To form these conductive vias 221, 231, it is possible to start from a device as described above in connection with FIG. 4F or FIG. 5D, that is coated with one or more insulating layers, for example with an insulating layer 223a of silicon nitride and an insulating layer 223a of silicon oxide.

Holes are subsequently produced in the insulating layers 223a, 223a that are subsequently filled with at least one conductive material.

Other metal levels and in particular one or more additional conductive lines on and in contact with the conductive vias 221, 231 (not shown in FIG. 7) may subsequently optionally be formed.

In a particular embodiment illustrated in FIG. 8, an upper portion of the non-volatile memory (NVM) structure forms a fourth conductive line 194 of the same metal interconnection level Mx as the third conductive line 163 and extends into another conductive via 191 to contact the first conductive line 111.

The assembly formed by the fourth conductive line 194 extended by the other conductive via 191 may have, in a cross-sectional plane (plane parallel to the plane [O;x;z] in FIG. 8 and passing through the fourth conductive line 194 and the other conductive via 191), a profile substantially identical to that of the assembly formed by the third conductive line 163 and the conductive via 161. The NVM structure in the form of a fourth conductive line 194 and the conductive via 191 may thus advantageously have a total cross section (section taken parallel to the plane [O;x;z]) substantially identical to the cross section of the third conductive line 163 and of the conductive via 161. Again, the NVM structure may be integrated into a metal level Mx and an inter-level region R12, following design rules similar to those adopted to form the conductive lines of the level Mx and vias Vx without having to provide for specific dimensions for this structure.

1. A microelectronic device, comprising:
a substrate including a plurality of superimposed metal interconnection levels,
a non-volatile memory structure arranged on a first conductive line of a first metal interconnection level, the non-volatile memory structure comprising a stack including a lower electrode and an upper electrode and at least one active material layer between the lower electrode and the upper electrode,
a second conductive line of said first metal interconnection level the second conductive line being distinct from the first conductive line, the first conductive line and the second conductive line being arranged in a same first plane parallel or substantially parallel to a main plane of the substrate, and
a third conductive line belonging to a second upper metal interconnection level in relation to said first interconnection level, the third conductive line being arranged in a second plane parallel to the main plane of the substrate and above the first plane such that the first plane is arranged between the second plane and the main plane of the substrate, the third conductive line being connected to the second conductive line by means of a conductive via, the conductive via extending into an intermediate region located between said first plane and said second plane, the lower electrode, the upper electrode and said at least one active material layer of said stack of the non-volatile memory structure extending into the second upper metal interconnection level and into said intermediate region, the third conductive line and the conductive via passing through an insulating thickness, the insulating thickness extending over the first conductive line and the second conductive line, said stack of the non-volatile memory structure lining the side walls as well as a bottom of a trench and of a hole located in the extension of this trench, the hole and the trench being arranged in said insulating thickness, said stack being disposed at the bottom of the hole on the first conductive line.

2. The microelectronic device according to claim 1, further comprising:
a first upper conductive via having a lower end disposed on and in contact with the non-volatile memory structure and extending, in an insulating thickness, between the lower end and an upper end, and
a second upper conductive via having a lower end disposed on and in contact with the third conductive line, and extending in said insulating thickness between the lower end thereof and an upper end,
the first upper conductive via and the second upper conductive via having equal respective heights measured between the lower end thereof on the one hand and the upper end thereof on the other hand.

3. The microelectronic device according to claim 2, wherein said conductive via has a lower end in contact with the second conductive line and an upper end in contact with the third conductive line, said conductive via and the third conductive line being arranged in at least one insulating layer, a lower face of the insulating layer being disposed on and in contact with the first conductive line and with the second conductive line, and
the non-volatile memory structure extends entirely in said insulating layer, between the lower face of the insulating layer and a plane passing through both an upper face of the insulating layer opposite the lower face, the lower end of the first upper conductive via and through the lower end of the second upper conductive via.

4. The microelectronic device according to claim 1, wherein the non-volatile memory structure comprises an upper portion and a lower portion, the lower portion extending into said intermediate region and having a height equal to or substantially equal to the height of said conductive via, the upper portion being arranged in the second plane and having a given cross section, the lower portion having a cross section different from the given cross section.

5. The microelectronic device according to claim 1, wherein the cumulative height of the hole and of the trench, is substantially equal to a cumulative height of the conductive via and of the third conductive line.

6. The microelectronic device according to claim 4, wherein said hole is provided with a width W1, and wherein the trench is provided with a width W2 such that W2>W1, such that the non-volatile memory structure includes a lower portion and an upper portion enlarged in relation to the lower portion.

7. The microelectronic device according to claim 6, wherein the lower electrode, the upper electrode, and the at least one active material layer of said stack of the non-volatile memory structure extend in a form of a fourth conductive line distinct from the third conductive line and belonging to the second metal interconnection level and in a form of at least one other conductive via in the extension of the fourth conductive line, said other conductive via being provided to make contact on the first conductive line.

8. The microelectronic device according to claim 7, wherein the fourth conductive line and said other via, have a cross section substantially identical to the cross section of the third conductive line and of said conductive via.

9. The microelectronic device according to claim 1, further comprising an additional conductive via arranged on and in contact with an upper portion of the memory structure.

10. The microelectronic device according to claim 9, wherein the upper electrode layer is provided or coated with an area of conductive material for filling the hole and the trench, said additional conductive via being disposed on and in contact with said upper portion of the memory structure without being disposed in contact with the active material or the lower electrode.

11. The microelectronic device according to claim 1, wherein the non-volatile memory structure is:
of the FeRAM type, the active material being formed of at least one layer of ferroelectric dielectric,
of the OXRAM type, the active material being formed of at least one dielectric layer,
of the CBRAM type, the active material being formed of at least one layer forming an electrolyte, or
of the FTJ type, the active material being formed of at least one layer of ferroelectric dielectric in contact with a layer of another dielectric material.

12. A method for manufacturing the microelectronic device according to claim 1, provided with the non-volatile memory structure formed of the stack including the at least one lower electrode and the at least one upper electrode and the at least one active material between the lower electrode and the upper electrode, the method comprising:
providing the substrate coated with at least one insulating layer, the first conductive line and the second conductive line of a given interconnection level extending in the insulating layer and in the same first plane parallel to the main plane of the substrate,
forming the insulating thickness on the first conductive line, the second conductive line and said insulating layer,
forming in said insulating thickness, the hole revealing the first conductive line and the trench in the extension of the hole,
depositing in the trench and in the hole the stack comprising at least one lower electrode layer, the at least one active material layer and the at least one upper electrode layer, said stack lining the side walls and a bottom of the hole and of the trench.

13. The method according to claim 12, further comprising forming in said insulating thickness a conductive via in contact with the second conductive line and the third conductive line on said conductive via.

14. The method according to claim 13, wherein producing the conductive via and the third conductive line comprises:
producing a first masking facing the first conductive line and including at least one opening facing the second conductive line,
etching through said opening of the first masking another trench and another hole in the extension of said other trench and having a bottom revealing the second conductive line, and
filling the other trench and the other hole using at least one conductive material, the method further comprising:
removing said first masking and forming a second masking including at least one opening facing the first conductive line, and etching the insulating thickness through said opening of said second masking to form said trench and said hole.

15. The method according to claim 13, wherein producing the conductive via and the third conductive line comprises forming another trench and another hole in the extension of said other trench, said other hole having a bottom revealing the second conductive line,
said hole revealing the first conductive line and said other hole revealing the second conductive line being formed concomitantly.

16. The method according to claim 13, wherein said trench, said other trench, said hole and said other hole are formed by etching the insulating thickness through one or more openings of a first masking, the method comprising:
filling said trench, said other trench, said hole and said other hole using at least one conductive material,
removing said first masking and forming a second masking facing the second conductive line and the third conductive line, the second masking including at least one opening facing the first conductive line,
removing said conductive material from said trench and from said hole by etching through the opening of said second masking, so as to again release said trench and said hole, and
forming said stack in said trench and said hole.

17. The method according to claim 12, the deposition of the stack being a compliant deposition performed in particular by ALD.

18. The method according to claim 12, wherein said at least one active material layer is formed:
of a ferroelectric dielectric, in particular an oxide such as Si-doped HfO₂ or HfZrO₂,
of a dielectric oxide such as HfO₂,
of a metal oxide such as HfO₂ or Al₂O₃ or Ta₂O₅ or of a chalcogenide such as GeSe or GeTe or GeSbTe, or
of a stack of a ferroelectric dielectric and of another dielectric.

19. The method according to claim 18, wherein the lower electrode and the lower electrode are formed:
of a layer made of a first material selected from one or more of the following materials: Ti, TiN, and W, or
of a layer made of a metal material selected from one or more of the following materials: W, Cu, Al, AlCu, and AlSi.

20. The manufacturing method according to claim 12, wherein the deposition in the trench and in the hole of said stack is followed by filling the trench and the hole by depositing a metal material, so as to fill the hole and the trench.
